(19) United States
(12) Patent Application Publication
(10) Pub. No.: US 2024/0266409 A1
(43) Pub. Date: Aug. 8, 2024

(54) BACKSIDE CONTACT FORMATION

(71) Applicant: INTERNATIONAL BUSINESS MACHINES CORPORATION, ARMONK, NY (US)

(72) Inventors: Tsung-Sheng Kang, Ballston Lake, NY (US); Curtis S. Durfee, Schenectady, NY (US); Ruqiang Bao, Niskayuna, NY (US); Chih-Chao Yang, Glenmont, NY (US)

(21) Appl. No.: 18/164,651

(22) Filed: Feb. 6, 2023

(51) Int. Cl. H01L 29/417; H01L 21/8234; H01L 27/088; H01L 29/06; H01L 29/423; H01L 29/775

(52) U.S. Cl. CPC H01L 29/4175; H01L 21/823475; H01L 27/088; H01L 29/0673; H01L 29/42392; H01L 29/775

(57) ABSTRACT

Embodiments of present invention provide a method of forming backside source/drain contact. The method includes forming a dummy contact structure in a substrate, the dummy contact structure having a central portion and a side portion, the central portion being higher than the side portion to have a height above the substrate; forming a source/drain region of a first transistor and a second transistor above the dummy contact structure, the first and second transistors being above the substrate; removing the dummy contact structure from a backside of the substrate to create a backside contact opening; and forming a backside source/drain contact by filling the backside contact opening with a conductive material. Structure of the backside source/drain contact formed thereby is also provided.

### BACKGROUND

The present application generally relates to manufacturing of semiconductor integrated circuits. More particularly, it relates to method of forming backside contact of semiconductor transistors and structures formed thereby.

With the increased demand for high density of semiconductor integrated circuitry, power supplies and some signal routing functionalities are being moved to the backside of the semiconductor chip or wafer for better usage of the real estate at the frontside. In the process of making backside source/drain contact, a placeholder dummy material is usually first formed in the source/drain region during a process of forming front-end-of-line (FEOL) structures. The dummy material is subsequently removed, when the process is moved to the backside of the semiconductor wafer to form power supplies, and replaced with some type of conductive or metal material to form backside source/drain contacts.

Currently, the dummy material used as placeholder is usually silicon-germanium (SiGe) and the placeholder may be formed through an epitaxial growth process. However, source/drain epitaxial regions of the semiconductor transistors are usually formed immediately above and next to the SiGe placeholder. Because of the proximity, the removal process of the placeholder, when being processed from the backside of the semiconductor wafer, has been found difficult without causing structural damage to the source/drain regions of the transistor, to which the backside source/drain contacts are supposed to provide power supplies.

### SUMMARY

Embodiments of present invention provide a semiconductor structure. The semiconductor structure includes a backside source/drain contact, where a central portion of the backside source/drain contact extends further, than a side portion of the backside source/drain contact, into a source/drain region of a first transistor and a second transistor. By extending into the source/drain region of the first and second transistors, the backside source/drain contact is effectively placed closer to the silicon channels of the first and second transistors thereby reducing or lowering the transfer resistance from the source/drain contacts to the silicon channels.

In one embodiment, the backside source/drain contact includes an upper portion; a middle portion; and a bottom portion, and the upper portion of the backside source/drain contact has a diamond shape and situates horizontally between the first transistor and the second transistor. The diamond shape of the upper portion of the backside source/drain contact brings the backside source/drain contact closer to the silicon channels of the first and second transistors.

In another embodiment, the middle portion of the backside source/drain contact is at least partially embedded in a substrate and a sidewall of the middle portion of the backside source/drain contact is surrounded by a dielectric liner.

In yet another embodiment, the first and second transistors are nanosheet transistors formed on top of the substrate and share the source/drain region, and where the source/drain region saddles on top of the upper portion of the backside source/drain contact.

In one embodiment, at least the first transistor is a nanosheet transistor having a set of nanosheets, and the central portion of the backside source/drain contact has a height that is higher than a bottom surface of a bottom-most nanosheet of the set of nanosheets.

Embodiments of present invention also provide a method of forming backside source/drain contact. The method includes forming a dummy contact structure in a substrate, the dummy contact structure having a central portion and a side portion, the central portion being higher than the side portion to have a height above the substrate; forming a source/drain region of a first transistor and a second transistor above the dummy contact structure, the first and second transistors being above the substrate; removing the dummy contact structure from a backside of the substrate to create a backside contact opening; and forming a backside source/drain contact by filling the backside contact opening with a conductive material. With the dummy contact structure having a central portion that is higher than a side portion and above the substrate, the later resulting backside source/drain contact may be made closer to the channel or channel regions of the first and second transistors. The closer distance in-turn reduces or lowers a transfer resistance between the backside source/drain contact and the channels of the first and second transistors.

In one embodiment, forming the dummy contact structure includes creating a dummy contact opening in the substrate; forming a dielectric liner lining a sidewall of the dummy contact opening; and epitaxially growing the dummy contact structure from the substrate at a bottom of the dummy contact opening such that an upper portion of the dummy contact structure has a diamond shape.

In another embodiment, forming the backside source/drain contact includes forming the backside source/drain contact to have an upper portion; a middle portion; and a bottom portion, where the upper portion of the backside source/drain contact has the diamond shape of the dummy contact structure. The diamond shape of the upper portion of the backside source/drain contact brings the backside source/drain contact closer to the channel regions of the transistors thereby lowering or reducing a transfer resistance between the backside source/drain contact and the channel regions of the transistors.

According to one embodiment, the method further includes, before forming the source/drain region, oxidizing a top surface of the dummy contact structure to form an etch-stop layer, where removing the dummy contact structure from the backside of the substrate includes selectively removing the dummy contact structure relative to the etch-stop layer. The use of the etch-stop layer helps prevent causing damages to the source/drain region during the process of removing the dummy contact structure, thereby resulting in a smooth bottom surface of the source/drain region.

According to another embodiment, the method further includes, after removing the dummy contact structure, selectively removing the etch-stop layer relative to the source/drain region, thereby creating the backside contact opening having a shape that is similar to the diamond shape of the dummy contact structure.

### BRIEF DESCRIPTION OF THE DRAWINGS

The present invention will be understood and appreciated more fully from the following detailed description of embodiments of present invention, taken in conjunction with accompanying drawings of which:

FIGS. 1-10 are demonstrative illustrations of cross-sectional views of a semiconductor structure in a process of manufacturing thereof according to embodiments of a method of present invention; and

FIG. 11 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

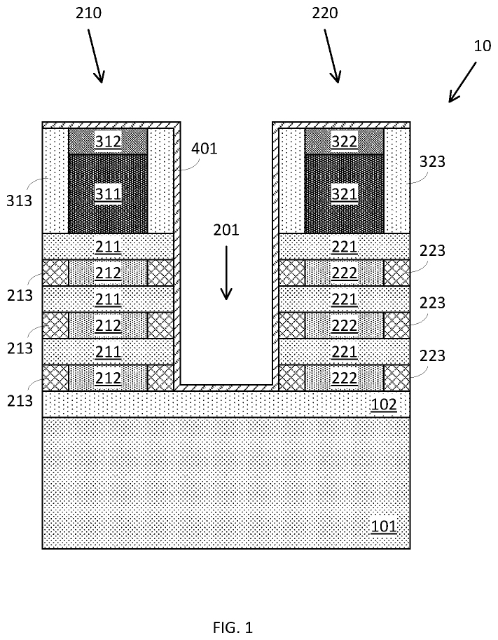

FIG. 1 is a demonstrative illustration of cross-sectional view of a semiconductor structure in a step of manufacturing thereof according to one embodiment of a method of present invention. More particularly, embodiments of present invention provide forming a semiconductor structure 10 that includes a semiconductor substrate 101 and one or more transistor structures, such as a first transistor 210 and a second transistor 220, on top thereof. The first and second transistors 210 and 220 may be field-effect-transistors (FETs) such as, for example, planar transistors, fin-type transistors, nanosheet transistors, nanowire transistors, and other types of transistors. Hereinafter, for the sake of description of various embodiments of present invention without losing generality, as a non-limiting example, the first and second transistors 210 and 220 may be described as nanosheet transistors.

More specifically, the transistor 210 may be formed on top of the substrate 101, via a bottom dielectric isolation (BDI) such as a dielectric layer 102, to include a first set of nanosheets 211 separated by a first set of dummy sheets 212. The nanosheets 211 may be silicon (Si) or silicon-germanium (SiGe) of a first SiGe concentration level, and the dummy sheets 212 may be SiGe of a second SiGe concentration level. The use of different SiGe concentration levels enables a selective etching process of the dummy sheets 212 relative to the nanosheets 211. Indentations 213 may be formed at a left side and a right side of the dummy sheets 212. A dummy gate 311 may be formed on top of the nanosheets 211. The dummy gate 311 may be covered by a hard mask 312 with sidewall spacers 313 at a left and a right sidewall thereof.

Similar to the transistor 210, the transistor 220 may be formed to include a second set of nanosheets 221 separated by a second set of dummy sheets 222. Indentations 223 may be formed at a left side and a right side of the dummy sheets 222. A dummy gate 321 may be formed on top of the nanosheet 221, which is covered by a hard mask 322 with sidewall spacers 323 at a left and a right sidewall thereof.

In the process of forming the transistors 210 and 220, a source/drain (S/D) recess 201 may be formed between the first set of nanosheets 211 and the second set of nanosheets 221. Embodiments of present invention further provide forming a dielectric liner 401 such as a silicon-nitride (SiN) liner lining, in the S/D recess 201, sidewalls of the first set of nanosheets 211 and the second set of nanosheets 221 and a top surface of an exposed portion of the dielectric layer 102 above the substrate 101.

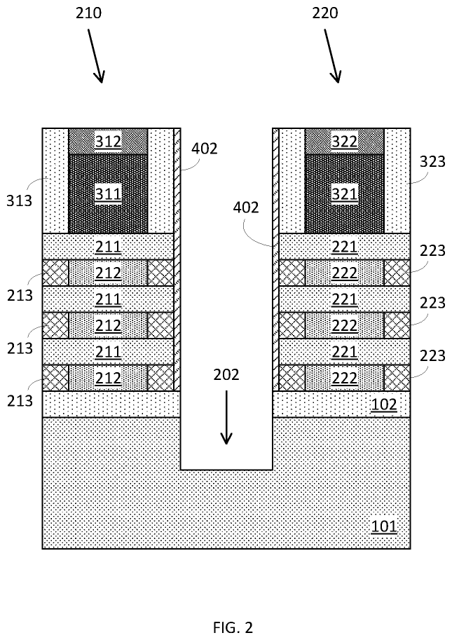

FIG. 2 is a demonstrative illustration of cross-sectional view of a semiconductor structure in a step of manufacturing thereof according to one embodiment of a method of present invention. More particularly, following the step illustrated in FIG. 1, embodiments of present invention provide performing a directional etching process, such as a reactive-ion-etching (RIE) process, to remove the horizontal portion of the dielectric liner 401, resulting a dielectric liner 402 of the vertical portion of the dielectric liner 401. The dielectric liner 402 covers thereby protects sidewalls of the first and the second set of nanosheets 211 and 221 from subsequent processing steps.

After removing the horizontal portion of the dielectric liner 401 above the dielectric layer 102, embodiments of present invention provide further etching through the exposed dielectric layer 102 and subsequently etching the underneath substrate 101 thereby creating a dummy contact opening 202 in the dielectric layer 102 and the substrate 101 for forming a dummy contact structure.

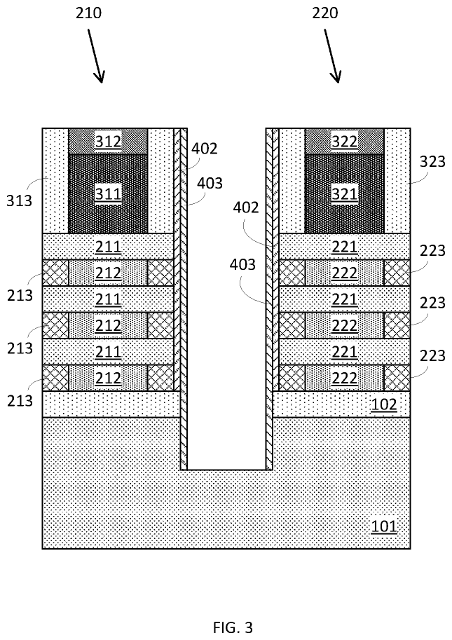

FIG. 3 is a demonstrative illustration of cross-sectional view of a semiconductor structure in a step of manufacturing thereof according to one embodiment of a method of present invention. More particularly, following the step illustrated in FIG. 2, embodiments of present invention provide forming a dielectric liner 403, such as a silicon-carbonitride (SiCN), silicon-oxycarbonitride (SiOCN), or silicoboron-carbonitride (SiBCN), lining a sidewall of the dummy contact opening 202. More particularly, the dielectric liner 403 may be formed by first forming a conformal dielectric liner covering the sidewall and a bottom of the dummy contact opening 202 and covering the dielectric liner 402 and on top of the first and the second sets of nanosheets 211 and 221. A directional and/or selective etching process may be applied to remove horizontal portions of the conformal dielectric liner leaving only vertical portions of the conformal dielectric liner, that is the dielectric liner 403, covering the sidewall of the dummy contact opening 202 and the dielectric liner 402. The directional etching process exposes the substrate 101 at the bottom of the dummy contact opening 202.

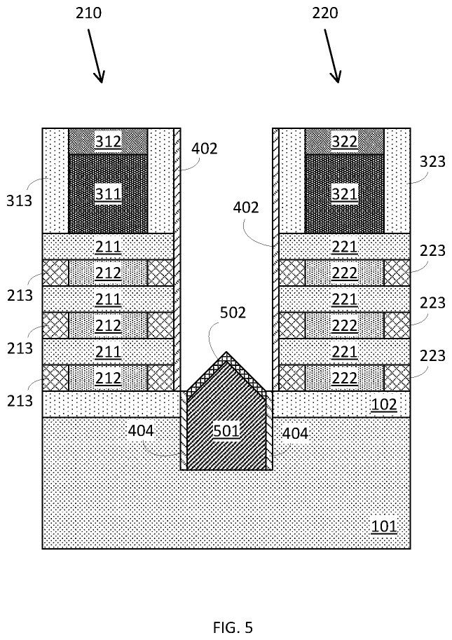

In one embodiment, the dielectric liner 403 of SiCN, SiOCN, or SiBCN is materially different from that of the dielectric liner 402, which may be for example SiN, and is also materially different from the etch-stop layer 502 (see FIG. 5), which may be for example SiO₂. In another embodiment, the dielectric liner 403 may be SiN and the dielectric liner 402 may be SiCN, SiOCN, or SiBCN so long as the dielectric liners 402 and 403 are materially different to have different etch selectivity. The difference in materials enables selective etching processes among the three as being described below in more details.

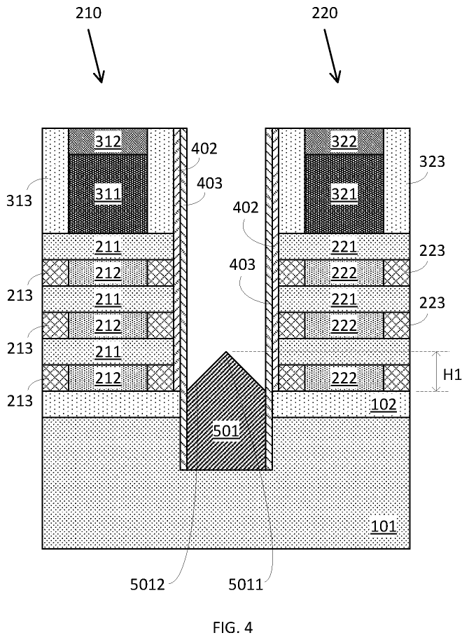

FIG. 4 is a demonstrative illustration of cross-sectional view of a semiconductor structure in a step of manufacturing thereof according to one embodiment of a method of present invention. More particularly, following the step illustrated in FIG. 3, embodiments of present invention provide epitaxially growing a dummy contact structure 501 in the dummy contact opening 202. For example, the dummy contact structure 501 may be formed by epitaxially growing a silicon-germanium (SiGe) from the substrate 101 at the bottom of the dummy contact opening 202 while the sidewall of the dummy contact opening 202 is covered by the dielectric liner 403 therefore no epitaxial growth starts from the sidewall. The dummy contact structure 501 formed by the epitaxial growth process may have a central portion 5011 and a side portion 5012, where the central portion 5011 is higher than the side portion 5012 to have a height H1 above the substrate 101 and above the dielectric layer 102. More particularly, an upper portion of the dummy contact structure 501 may be epitaxially grown to have a diamond shape, as is illustrated in FIG. 4, with a pointy center. The diamond shape of the upper portion of the dummy contact structure 501 helps bring a backside source/drain contact closer to the first and second sets of nanosheets 211 and 221. This in-turn helps reducing or lowering a transfer resistance between the backside source/drain contact, which is formed later to replace the dummy contact structure 501, and the channels or channel regions of the first and second transistors 210 and 220.

FIG. 5 is a demonstrative illustration of cross-sectional view of a semiconductor structure in a step of manufacturing thereof according to one embodiment of a method of present invention. More particularly, following the step illustrated in FIG. 4, embodiments of present invention provide selectively removing, for example through a selective etching process, an exposed portion of the dielectric liner 403 that is not covered by the dummy contact structure 501. For example, at least a portion of the dielectric liner 403 that is adjacent to the dielectric liner 402 and above a level of the dielectric layer 102 may be selectively etched away, resulting a dielectric liner 404 lining the opening surrounded by the dielectric layer 102 and the substrate 101. The dielectric liner 404 is directly adjacent to and surrounds the dummy contact structure 501. In the meantime, since the dielectric liners 402 and 403 are made of materials with different etch selectivity, such as SiN vs SiCN, the dielectric liner 402 may remain largely unaffected or unetched, and continue to protect the sidewalls of the first and second sets of nanosheets 211 and 221 in subsequent processing steps.

Embodiments of present invention further provide performing an oxidation process to oxidize the exposed top surface of the dummy contact structure 501 to form an etch-stop layer 502, such as an oxide layer, covering the diamond shaped dummy contact structure 501. For example, the oxidation process may be performed in an environment containing oxygen at an elevated temperature ranging from about 700 Celsius (C) to about 1200 C and for a duration of 180 to 600 seconds, and the etch-stop layer 502 so created may have a thickness around 2˜7 nm. The etch-stop layer 502 helps enabling a selective etching process, which in-turn helps the removing of the dummy contact structure 501 later, without causing damage to a source/drain region formed above the etch-stop layer 502.

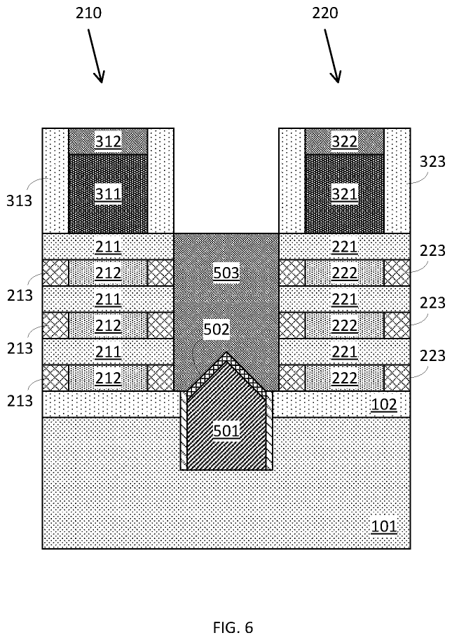

FIG. 6 is a demonstrative illustration of cross-sectional view of a semiconductor structure in a step of manufacturing thereof according to one embodiment of a method of present invention. More particularly, following the step illustrated in FIG. 5, embodiments of present invention provide selectively removing the dielectric liner 402 that protected the sidewalls of the first and second sets of nanosheets 211 and 221 during the oxidation process of the dummy contact structure 501; and epitaxially growing a source/drain region 503 above the dummy contact structure 501. For example, in one embodiment, the source/drain region 503 may be epitaxial grown silicon-germanium, starting from sidewalls of the first and second sets of nanosheets 211 and 221.

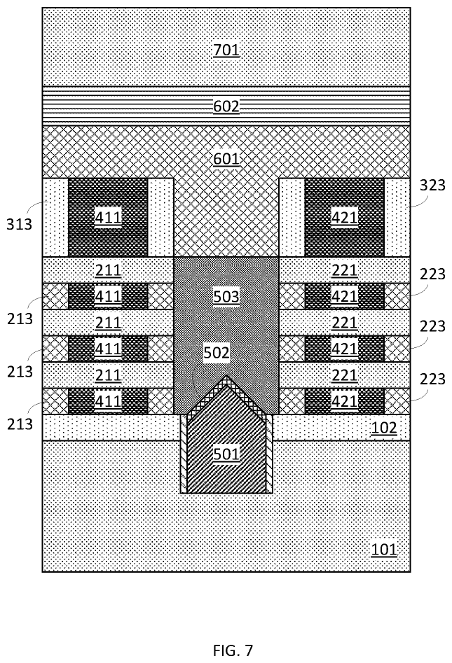

FIG. 7 is a demonstrative illustration of cross-sectional view of a semiconductor structure in a step of manufacturing thereof according to one embodiment of a method of present invention. More particularly, following the step illustrated in FIG. 6, embodiments of present invention provide forming a first set of metal gates 411 and a second set of metal gates 421 surrounding and above the first set of nanosheets 211 and the second set of nanosheets 221 respectively. The formation of the first and the second set of metal gates 411 and 421 may be made through a replacement metal gate (RMG) process by selectively removing the first and the second set of dummy sheets 212 and 222 and replacing them with gate metals such as, for example, titanium-nitride (TiN), titanium-carbon (TiC), copper (Cu), ruthenium (Ru), cobalt (Co), tungsten (W), and aluminum (Al), to surround the first and second sets of nanosheets 211 and 221, thereby forming the first set and the second set of metal gates 411 and 421.

Embodiments of present invention provide further forming a dielectric layer 601 above the first set and the second set of nanosheets 211 and 221 of the first and the second transistor 210 and 220, including above the source/drain region 503; and forming a back-end-of-line (BEOL) structure 602, above the dielectric layer 601, which includes one or more metal levels for device powering and signal routing. A carrier wafer 701 is then bonded onto the BEOL structure 602 such that the semiconductor structure 10 may be flipped upside-down for further processing from a backside of the semiconductor substrate 101.

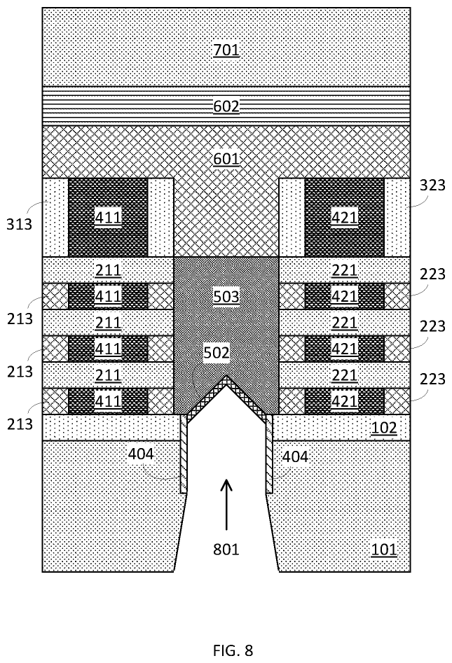

FIG. 8 is a demonstrative illustration of cross-sectional view of a semiconductor structure in a step of manufacturing thereof according to one embodiment of a method of present invention. Here, for illustration purpose only the semiconductor structure 10 is not shown as being flipped upside-down but a person skilled in the art will appreciate that the following process steps are made from the backside of the substrate 101.

More particularly, following the step illustrated in FIG. 7, embodiments of present invention provide creating an opening in the substrate 101, from the backside of the substrate 101, to expose the dummy contact structure 501. The exposed dummy contact structure 501 is then removed through a selective etching process. Because the dummy contact structure is made of a material, such as SiGe, different from that of the dielectric liner 404 and the etch-stop layer 502, such as SiC and SiO₂ respectively, embodiments of present invention enables a selective etching process with which the dummy contact structure 501 may be selectively removed relative to the dielectric liner 404 and the etch-stop layer 502, resulting in an initial backside contact opening 801.

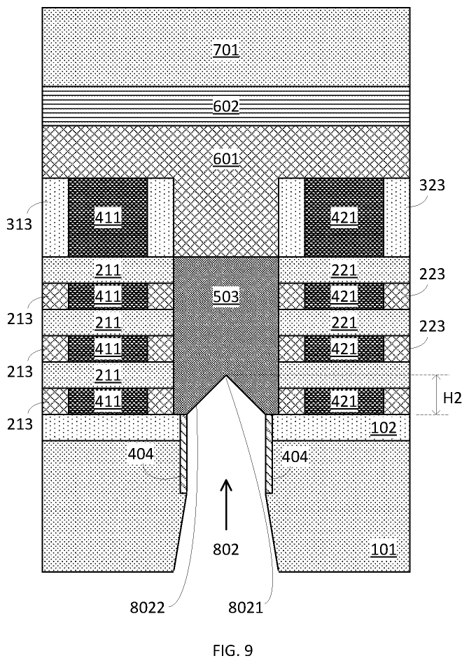

FIG. 9 is a demonstrative illustration of cross-sectional view of a semiconductor structure in a step of manufacturing thereof according to one embodiment of a method of present invention. More particularly, following the step illustrated in FIG. 8, embodiments of present invention provide removing the etch-stop layer 502. As being described above, since the etch-stop layer 502 is made of a material, such as SiO₂, different from that of the source/drain region 503, such as SiGe, and from that of the dielectric liner 404, such as SiCN, the etch-stop layer 502 may be removed through a selective etching process, thereby resulting a backside contact opening 802. The backside contact opening 802 may have an upper portion that has a significantly similar shape as the diamond shape of the dummy contact structure 501. In one embodiment, the interface with the source/drain region 503 may be smooth and flat (albeit with slope) without a zig-zag profile. The zig-zag profile may otherwise be caused by the removal process of the dummy contact structure 501 due to etch damage, if no etch-stop layer 502 is used.

For example, the upper portion of the backside contact opening 802 has a pointy center. The pointy center or central portion 8021 of the backside contact opening 802 may have a height H2 that is higher than a height of a side portion 8022 of the backside contact opening 802. For example, the height H2 of the central portion 8021 of the backside contact opening 802 may be between a top surface of the dielectric layer 102 and a top surface of a bottom-most nanosheet of the first set of nanosheets 211 or the second set of nanosheets 221. In one embodiment, the pointy center or central portion 8021 of the backside contact opening 802 may have a height H2 that is higher than a bottom surface of a bottom-most nanosheet of the first set of nanosheets 211 or the second set of nanosheets 221.

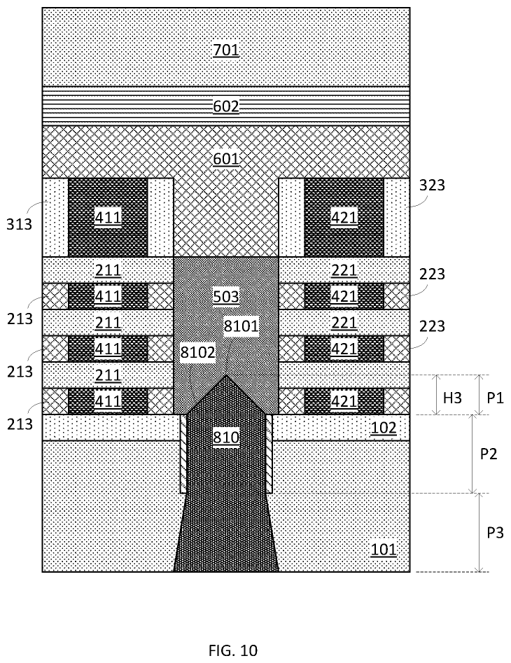

FIG. 10 is a demonstrative illustration of cross-sectional view of a semiconductor structure in a step of manufacturing thereof according to one embodiment of a method of present invention. More particularly, following the step illustrated in FIG. 9, embodiments of present invention provide forming a backside source/drain contact 810 by filling the backside contact opening 802 with a conductive material such as, for example, Cu, Ru, Co, W, Al and/or other suitable metal or metal alloy. The backside source/drain contact 810 may have an upper portion P1, a middle portion P2, and a bottom portion P3. The upper portion P1 of the backside source/drain contact 810 may have a diamond shape, or a shape that is significantly similar to the diamond shape of the upper portion of the dummy contact structure. In other words, a central portion 8101 of the backside source/drain contact 810 may extend upwardly further, than a side portion 8102 of the backside source/drain contact 810, into the source/drain region 503. The central portion 8101 of the backside source/drain contact 810 may have a height H3 that is higher than a bottom surface of a bottom-most nanosheet of the first set of nanosheets 211 or the second set of nanosheets 221. In the meantime, the middle portion P2 of the backside source/drain contact 810 may be surrounded by the dielectric liner 404, and at least partially embedded in the substrate 101.

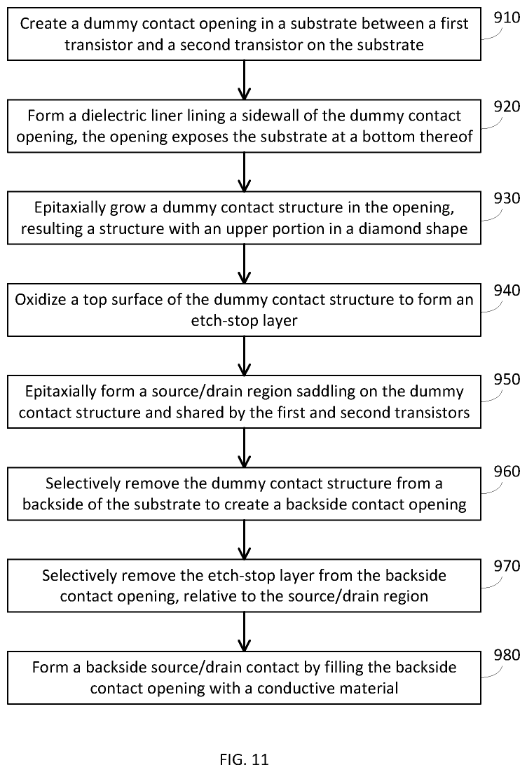

FIG. 11 is a demonstrative illustration of a flow-chart of a method of manufacturing a semiconductor structure according to embodiments of present invention. The method includes (910) forming creating a dummy contact opening in a substrate between a first and a second transistor such as between a first and a second nanosheet transistor on a frontside of the substrate; (920) forming a dielectric liner lining a sidewall of the dummy contact opening while leaving the substrate being exposed at a bottom of the dummy contact opening; (930) epitaxially growing a dummy contact structure in the dummy contact opening, the dummy contact structure being formed from the bottom of the dummy contact opening, while a sidewall of the dummy contact opening being covered by the dielectric liner, thereby resulting the dummy contact structure to have an upper portion with a diamond shape; (940) oxidizing a top surface of the dummy contact structure to form an etch-stop layer; (950) epitaxially forming a source/drain region over the dummy contact structure, resulting in a source/drain region, shared by the first and the second transistors, that saddles on top of the dummy contact structure; (960) selectively removing the dummy contact structure from a backside of the substrate to create a backside contact opening; (970) selectively removing the etch-stop layer from the backside contact opening, relative to and thereby expose the source/drain region; and (980) form a backside source/drain contact by filling the backside contact opening with a conductive material.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a backside source/drain contact, wherein a central portion of the backside source/drain contact extends further, than a side portion of the backside source/drain contact, into a source/drain region of a first transistor and a second transistor.

2. The semiconductor structure of claim 1, wherein the backside source/drain contact includes an upper portion; a middle portion; and a bottom portion, and the upper portion of the backside source/drain contact has a diamond shape and situates horizontally between the first transistor and the second transistor.

3. The semiconductor structure of claim 2, wherein the middle portion of the backside source/drain contact is at least partially embedded in a substrate and a sidewall of the middle portion of the backside source/drain contact is surrounded by a dielectric liner.

4. The semiconductor structure of claim 3, wherein the first and second transistors are nanosheet transistors formed on top of the substrate and share the source/drain region, and wherein the source/drain region saddles on top of the upper portion of the backside source/drain contact.

5. The semiconductor structure of claim 1, wherein at least the first transistor is a nanosheet transistor having a set of nanosheets, and the central portion of the backside source/drain contact has a height that is higher than a bottom surface of a bottom-most nanosheet of the set of nanosheets.

6. A semiconductor structure comprising:
a first nanosheet transistor and a second nanosheet transistor on a substrate;
a source/drain region shared by the first and second nanosheet transistors; and
a backside source/drain contact underneath the source/drain region, wherein a central portion of the backside source/drain contact extends upwardly further, than a side portion of the backside source/drain contact, into the source/drain region.

7. The semiconductor structure of claim 6, wherein the backside source/drain contact includes an upper portion; a middle portion; and a bottom portion, and the upper portion of the backside source/drain contact has a diamond shape and situates above a height level of the substrate.

8. The semiconductor structure of claim 7, wherein a sidewall of the middle portion of the backside source/drain contact is surrounded by a dielectric liner.

9. The semiconductor structure of claim 8, wherein the source/drain region of the first and second nanosheet transistors saddles on top of the upper portion of the backside source/drain contact and is above the dielectric liner.

10. The semiconductor structure of claim 6, wherein the first transistor includes a set of nanosheets, and the central portion of the backside source/drain contact has a height that is higher than a bottom surface of a bottom-most nanosheet of the set of nanosheets.

11. A method comprising:
forming a dummy contact structure in a substrate, the dummy contact structure having a central portion and a side portion, the central portion being higher than the side portion to have a height above the substrate;
forming a source/drain region of a first transistor and a second transistor above the dummy contact structure, the first and second transistors being above the substrate;
removing the dummy contact structure from a backside of the substrate to create a backside contact opening; and
forming a backside source/drain contact by filling the backside contact opening with a conductive material.

12. The method of claim 11, wherein forming the dummy contact structure comprises:
creating a dummy contact opening in the substrate;
forming a dielectric liner lining a sidewall of the dummy contact opening; and
epitaxially growing the dummy contact structure from the substrate at a bottom of the dummy contact opening such that an upper portion of the dummy contact structure has a diamond shape.

13. The method of claim 12, wherein forming the backside source/drain contact comprises forming the backside source/drain contact to have an upper portion; a middle portion;
and a bottom portion, wherein the upper portion of the backside source/drain contact has the diamond shape of the dummy contact structure.

14. The method of claim 12, further comprising, before forming the source/drain region, oxidizing a top surface of the dummy contact structure to form an etch-stop layer, wherein removing the dummy contact structure from the backside of the substrate comprises selectively removing the dummy contact structure relative to the etch-stop layer.

15. The method of claim 14, further comprising, after removing the dummy contact structure, selectively removing the etch-stop layer relative to the source/drain region, thereby creating the backside contact opening having a shape that is similar to the diamond shape of the dummy contact structure.

16. The method of claim 15, wherein the etch-stop layer is an oxide layer having a thickness around 2˜7 nm and wherein selectively removing the etch-stop layer comprises applying a selective etching process that is selective relative to both the dielectric liner and the source/drain region.

17. The method of claim 11, wherein the dummy contact structure and the source/drain region are epitaxially formed silicon-germanium.

18. The method of claim 11, wherein at least the first transistor is a nanosheet transistor having a set of nanosheets, and a central portion of the backside source/drain contact has a height that is higher than a bottom surface of a bottom-most nanosheet of the set of nanosheets.

19. The method of claim 11, wherein removing the dummy contact structure from the backside of the substrate comprises creating an opening in the substrate, from the backside of the substrate, that exposes the dummy contact structure.

20. The method of claim 11, further comprising forming a first and a second metal gate of the first and the second transistor before removing the dummy contact structure.
